(19) United States
(12) Patent Application Publication
(10) Pub. No.: US 2007/0054149 A1
(43) Pub. Date: Mar. 8, 2007

(54) Substrate assembly of a display device and method of manufacturing the same

(76) Inventors: Chi-Ming Cheng, Chu-Nan (TW); Chien-Chih Chiang, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/208,709

(22) Filed: Aug. 23, 2005

(51) Int. Cl. H01L 51/52; H01L 51/56

(52) U.S. Cl. 428/690; 428/335; 428/698; 428/917; 313/112; 257/98; 427/66

(57) ABSTRACT

A substrate assembly of a display device and a method of manufacturing the same are disclosed. The substrate assembly includes a transparent substrate, an optical wavelength conversion layer and an inorganic covering layer. The optical wavelength conversion layer is formed on the transparent substrate. The inorganic covering layer is covered on the optical wavelength conversion layer. Moreover, the substrate assembly is used to support an organic emission element. Whereby the substrate assembly and the organic emission element are assembled together to form a display device. Furthermore, the substrate assembly further includes an inorganic barrier layer formed on the optical wavelength conversion layer and/or on the inorganic covering layer for preventing the organic emission element from being damaged by the moistures or the outgas produced from the optical wavelength conversion layer during heating process.

### BACKGROUND OF THE INVENTION

1. Field of The Invention

The present invention relates to a substrate assembly of a display device and a method of manufacturing the same, and particularly relates to a substrate assembly for prevent an organic emission element from being damaged by moisture or outgas during heating process at 100 to 260° C.

2. Description of the Related Art

FIG. 1 shows a cross-sectional view of an OLED in accordance with the prior art. The OLED of the prior art includes a glass substrate 10, an optical wavelength conversion layer 20 and a black matrix 30 alternately formed on the glass substrate 10, an organic covering layer 40 formed on the optical wavelength conversion layer 20, an inorganic barrier layer 45 formed on the organic covering layer 40, and an organic emission element 50 assembled on the inorganic barrier layer 45.

Moreover, the inorganic barrier layer 45 is formed on the organic covering layer 40 for preventing the organic emission element 50 from being damaged by the moisture or the outgas from the optical wavelength conversion layer 20 and/or the organic covering layer 40 during heating process. Furthermore, after forming the organic covering layer 40 on the optical wavelength conversion layer 20, the top surface of the organic covering layer 40 needs to be cleaned. However, moistures or outgas are easily absorbed by the opening of the organic covering layer 40 during the cleaning process, and the moistures or the outgas in the opening are vapored to affect the organic emission element 50 in other processes. Moreover, because the organic covering layer 40 is organic material, moistures or outgas are easily produced from the organic covering layer 40 to affect or damage the organic emission element 50.

### SUMMARY OF THE INVENTION

The present invention provides a substrate assembly of a display device and a method of manufacturing the same. The substrate assembly has an inorganic barrier layer formed on an optical wavelength conversion layer and/or on an inorganic covering layer for preventing the organic emission element from being damaged by the moistures or the outgas produced from the optical wavelength conversion layer during heating process, and prevent the optical wavelength conversion layer from being damaged by cleaning process before making the inorganic covering layer.

Furthermore, the present invention provides the inorganic covering layer that is made of inorganic material. Hence the structure of the inorganic covering layer is very compact, and the inorganic covering is hard to absorb moistures or outgas. Whereby, the inorganic covering layer can prevent the organic emission element from being damaged by moistures or the outgas produced from a transparent substrate.

One aspect of the invention is a substrate assembly. The substrate assembly includes a transparent substrate, an optical wavelength conversion layer and an inorganic covering layer. The optical wavelength conversion layer is formed on the transparent substrate. The inorganic covering layer is covered on the optical wavelength conversion layer. Moreover, the substrate assembly is used to support an organic emission element. Whereby the substrate assembly and the organic emission element are assembled together to form a display device.

Furthermore, the substrate assembly further includes an inorganic barrier layer formed on the optical wavelength conversion layer and/or on the inorganic covering layer for preventing the organic emission element from being damaged by the moistures or the outgas produced from the optical wavelength conversion layer during heating process.

One aspect of the invention is a method of manufacturing a substrate assembly. The method includes providing a transparent substrate; forming an optical wavelength conversion layer on the transparent substrate; and covering an inorganic covering layer on the optical wavelength conversion layer.

Moreover, the method further includes forming an inorganic barrier layer on the optical wavelength conversion layer and/or on the inorganic covering layer. Furthermore, an organic emission element can be assembled on the inorganic barrier layer to form a display device after forming the inorganic barrier layer on the optical wavelength conversion layer. In addition, the method further includes a planarization process after covering the inorganic covering layer on the optical wavelength conversion layer or on the inorganic barrier layer.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objectives and advantages of the present invention will be more readily understood from the following detailed description when read in conjunction with the appended drawing, in which:

FIG. 1 is a cross-sectional view of an OLED in accordance with the prior art;

FIG. 2 is a cross-sectional view of an OLED in accordance with the first embodiment of the present invention;

FIG. 3 is a cross-sectional view of an OLED in accordance with the second embodiment of the present invention;

FIG. 4 is a cross-sectional view of an OLED in accordance with the third embodiment of the present invention;

FIGS. 5A to 5C respectively are three cross-sectional views of manufacturing an OLED in accordance with the first embodiment of the present invention; and

FIG. 6 is a flow chart of a method of manufacturing a substrate assembly in accordance with the first embodiment of the present invention.

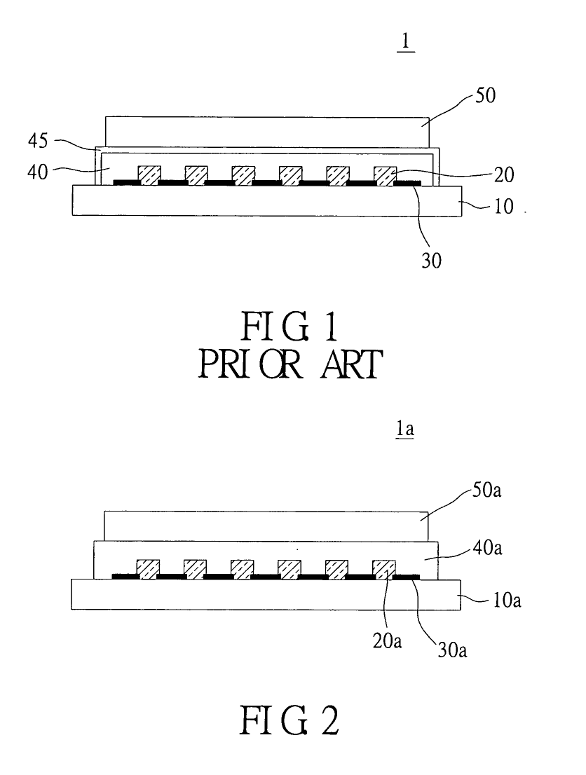

### DETAILED DESCRIPTION OF PREFERRED EMBODIMENTS

FIG. 2 shows a cross-sectional view of an OLED (Organic Electro-Luminescence Display) in accordance with the first embodiment of the present invention. The OLED 1a includes a transparent substrate 10a, an optical wavelength conversion layer 20a, an inorganic covering layer 40a and an organic emission element 50a. The optical wavelength conversion layer 20a is formed on the transparent substrate 10a. The inorganic covering layer 40a is covered on the optical wavelength conversion layer 20a. The organic emission element 50a is disposed on the inorganic covering layer 40a. Moreover, the transparent substrate 10a can be made of glass, quartz or plastic materials. The transparent substrate 10a has an active matrix or a passive matrix such as TFT (Thin Film Transistor). Furthermore, the organic emission element 50a can be an OLED (Organic Light Emitting Diode) or a PLED (Polymer Light Emitting Diode).

In addition, the inorganic covering layer 40a is made of a material selected from the group consisting of silicon oxide, silicon nitride, silicon nitride oxide, silicon carbide, titanium oxide, titanium nitride, zirconium oxide, zirconium nitride, aluminum oxide, aluminum nitride, tin oxide, indium oxide, lead oxide, boric oxide, calcium oxide, SiOₓCᵢHⱼ, SiN_{y}CᵢHⱼ and SiOₓN_{y}CᵢHⱼ. The inorganic covering layer 40a has a perfect thickness of from 1 to 50 μm for preventing the moisture or the outgas of the optical wavelength conversion layer 20a from spreading to the organic emission element 50a in a heating process. The inorganic covering layer 40a is a multi-layers structure. Moreover, the organic emission element 50a is easily formed on a plane top surface of the inorganic covering layer 40a. The optical wavelength conversion layer 20a can be a color filter (CF) layer, a color conversion medium (CCM) layer or a combination of the color filter layer and the color conversion medium layer. The organic emission element 50a can be white or blue. Furthermore, in order to ensure the display effect of the OLED, the inorganic covering layer 40a has a transmittance larger than 80%.

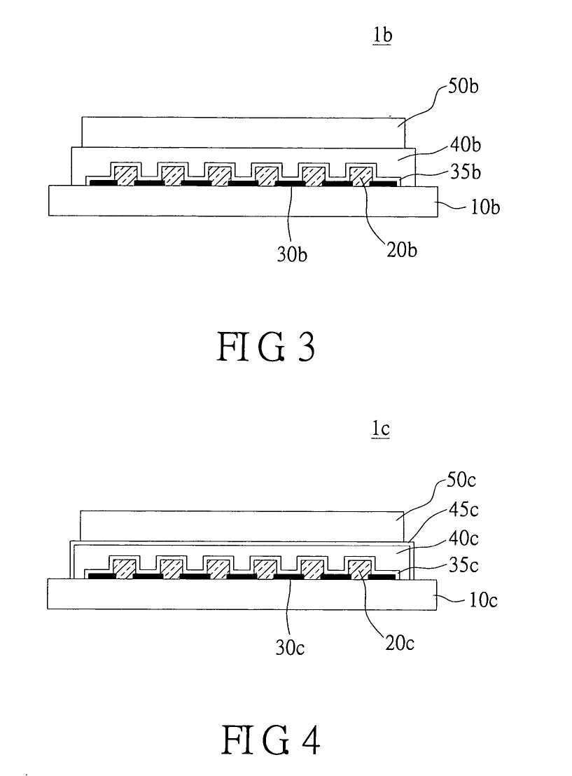

FIG. 3 shows a cross-sectional view of an OLED 1b in accordance with the second embodiment of the present invention. In order to prevent the organic emission element 50b from being damaged by the moisture or the outgas of the optical wavelength conversion layer 20b, and prevent the optical wavelength conversion layer 20b from being damaged by cleaning process before making the inorganic covering layer 40b, an inorganic barrier layer 35b can be formed on the optical wavelength conversion layer 20b by a CVD (Chemical Vapor Deposition) or PVD (Physical Vapor Deposition) method.

FIG. 4 shows a cross-sectional view of an OLED I c in accordance with the third embodiment of the present invention. In addition to form the inorganic barrier layer 35c on the optical wavelength conversion layer 20c, an inorganic barrier layer 45c can be formed on the inorganic covering layer 40c by the CVD or PVD method. The inorganic barrier layers 35c, 40c not only can prevent the organic emission element 50c from being damaged by the moisture or the outgas of the optical wavelength conversion layer 20c, but also can prevent a transparent electrode from being damaged by etching liquids during making element patterns. However, the inorganic barrier layer (35b, 35c or 45c) has a thickness smaller than that of the barrier layer 45 of the prior art. In other words, the thickness of the inorganic barrier layer (35b, 35c or 45c) is from 500×10⁻¹⁰ to 5000×10⁻¹⁰ m that has same effect as prior art. Moreover, the inorganic barrier layer (35b, 35c or 45c) can be a multi-layers structure.

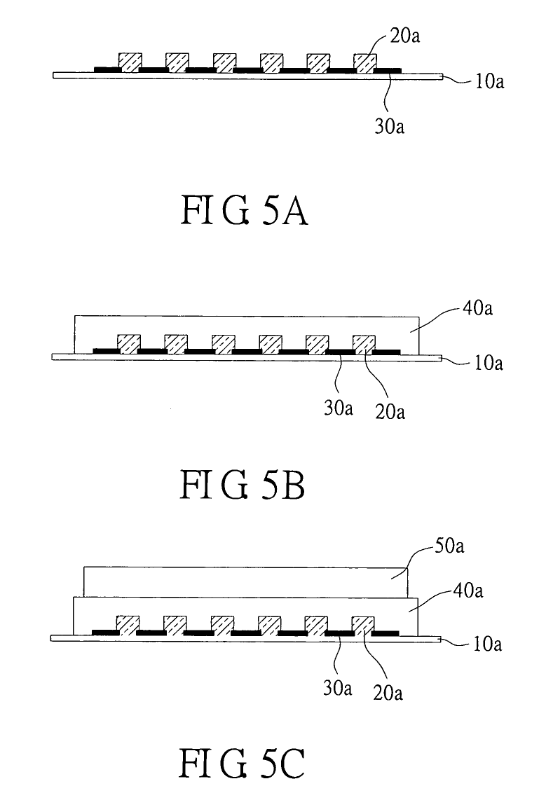

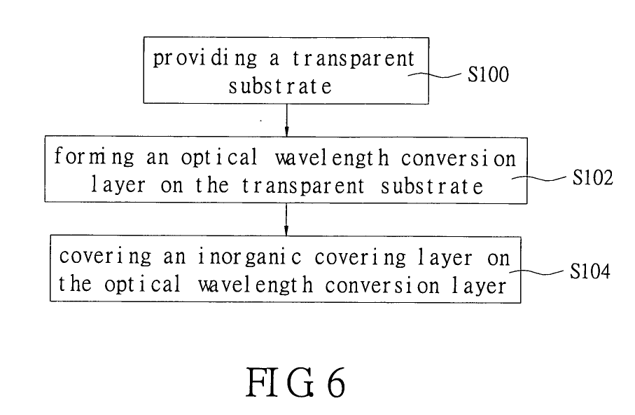

FIGS. 5A to 5C respectively show three cross-sectional views of manufacturing an OLED in accordance with the first embodiment of the present invention, and FIG. 6 shows a flow chart of a method of manufacturing a substrate assembly in accordance with the first embodiment of the present invention. The present invention provides a method of manufacturing a substrate assembly for display. The method includes: providing a glass substrate or a transparent substrate 10a with TFT array (S100); forming an optical wavelength conversion layer 20a on the transparent substrate 10a (S102), moreover the patterns of the optical wavelength conversion layer 20a are separated by a black matrix 30a; covering an inorganic covering layer 40a on the optical wavelength conversion layer 20a (S104). Furthermore, the inorganic covering layer 40a is made of a material selected from the group consisting of silicon oxide, silicon nitride, silicon nitride oxide, silicon carbide, titanium oxide, titanium nitride, zirconium oxide, zirconium nitride, aluminum oxide, aluminum nitride, tin oxide, indium oxide, lead oxide, boric oxide, calcium oxide, SiOₓCᵢHⱼ, SiN_{y}CᵢHⱼ and SiOₓN_{y}CᵢHⱼ. The inorganic covering layer 40a can be formed by a CVD, PVD or SOG (Spin On Glass) method. The inorganic covering layer 40a is a multi-layers structure. In addition, the method includes assembling an organic emission element 50a on the inorganic covering layer 40a.

Furthermore, the inorganic covering layer 40a has a thickness of from 1 to 50 μm, and the inorganic covering layer 40a is covered on the optical wavelength conversion layer at the temperature of between 20 and 300° C. and the pressure of between 0.0005 torr and 1 atm.

Moreover, the method further includes forming an inorganic barrier layer on the optical wavelength conversion layer and/or on the inorganic covering layer. Furthermore, an organic emission element can be assembled on the inorganic barrier layer to form a display device after forming the inorganic barrier layer on the optical wavelength conversion layer. In addition, the method further includes a planarization process after covering the inorganic covering layer on the optical wavelength conversion layer or on the inorganic barrier layer.

In conclusion, the inorganic barrier layer (35b, 35c or 45c) is provided to prevent the organic emission element (50a, 50b or 50c) from being damaged by the moistures or the outgas produced from the optical wavelength conversion layer (20a, 20b or 20c) during heating process, and prevent the optical wavelength conversion layer (20a, 20b or 20c) from being damaged by cleaning process before making the inorganic covering layer (40a, 40b or 40c).

Furthermore, the inorganic covering layer (40a, 40b or 40c) is made of inorganic material. Hence the structure of the inorganic covering layer (40a, 40b or 40c) is very compact, and the inorganic covering (40a, 40b or 40c) is hard to absorb moistures or outgas. Whereby, the inorganic covering layer (40a, 40b or 40c) can prevent the organic emission element (50a, 50b or 50c) from being damaged by the moistures or the outgas produced from a transparent substrate (10a, 10b or 10c).

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A substrate assembly comprising:
a transparent substrate;
an optical wavelength conversion layer formed on the transparent substrate; and
an inorganic covering layer covering on the optical wavelength conversion layer;
wherein the substrate assembly is used to support an organic emission element, the substrate assembly and the organic emission element are assembled together to form a display device.

2. The substrate assembly as claimed in claim 1, wherein the inorganic covering layer has a thickness of from 1 to 50 μm.

3. The substrate assembly as claimed in claim 1, further comprising an inorganic barrier layer formed on the optical wavelength conversion layer.

4. The substrate assembly as claimed in claim 1, further comprising an inorganic barrier layer formed on the inorganic covering layer.

5. The substrate assembly as claimed in claim 4, wherein the inorganic barrier layer has a thickness of from 500×10⁻¹⁰ to 5000×10⁻¹⁰ m.

6. The substrate assembly as claimed in claim 4, wherein the inorganic barrier layer is a multi-layers structure.

7. The substrate assembly as claimed in claim 1, wherein the inorganic covering layer is made of a material selected from the group consisting of silicon oxide, silicon nitride, silicon nitride oxide, silicon carbide, titanium oxide, titanium nitride, zirconium oxide, zirconium nitride, aluminum oxide, aluminum nitride, tin oxide, indium oxide, lead oxide, boric oxide, calcium oxide, SiOₓCᵢHⱼ, SiN_{y}CᵢHⱼ and SiOₓN_{y}CᵢHⱼ.

8. The substrate assembly as claimed in claim 1, wherein the optical wavelength conversion layer is a color filter layer, a color conversion medium layer or a combination of the color filter layer and the color conversion medium layer.

9. The substrate assembly as claimed in claim 1, wherein the inorganic covering layer is a multi-layers structure.

10. The substrate assembly as claimed in claim 1, wherein the organic emission element is an OLED (Organic Light Emitting Diode) or a PLED (Polymer Light Emitting Diode), and the transparent substrate is made of glass, quartz or plastic materials.

11. A method of manufacturing a substrate assembly, comprising:
providing a transparent substrate;
forming an optical wavelength conversion layer on the transparent substrate; and
covering an inorganic covering layer on the optical wavelength conversion layer.

12. The method as claimed in claim 11, wherein the inorganic covering layer has a thickness of from 1 to 50 μm made by a CVD (Chemical Vapor Deposition), PVD (Physical Vapor Deposition), or SOG (Spin On Glass) method.

13. The method as claimed in claim 11, wherein the inorganic covering layer is covered on the optical wavelength conversion layer at the temperature of between 20 and 300° C. and the pressure of between 0.0005 torr and 1 atm.

14. The method as claimed in claim 11, further comprising forming an inorganic barrier layer on the optical wavelength conversion layer.

15. The method as claimed in claim 14, further comprising assembling an organic emission element on the inorganic barrier layer after forming the inorganic barrier layer on the optical wavelength conversion layer.

16. The method as claimed in claim 11, further comprising forming an inorganic barrier layer on the inorganic covering layer.

17. The method as claimed in claim 16, wherein the inorganic barrier layer has a thickness of from 500×10⁻¹⁰ to 5000×10⁻¹⁰ m.

18. The method as claimed in claim 16, wherein the inorganic barrier layer or the inorganic covering layer is a multi-layers structure.

19. The method as claimed in claim 11, wherein the inorganic covering layer is made of a material selected from the group consisting of silicon oxide, silicon nitride, silicon nitride oxide, silicon carbide, titanium oxide, titanium nitride, zirconium oxide, zirconium nitride, aluminum oxide, aluminum nitride, tin oxide, indium oxide, lead oxide, boric oxide, calcium oxide, SiOₓCᵢHⱼ, SiN_{y}CᵢHⱼ and SiOₓN_{y}CᵢHⱼ.

20. The method as claimed in claim 11, further comprising a planarization process after covering the inorganic covering layer on the optical wavelength conversion layer.
